(19) United States
(12) Patent Application Publication
(10) Pub. No.: US 2025/0010807 A1
(43) Pub. Date: Jan. 9, 2025

(54) CLAMP, ELECTROMAGNETIC SHIELDING COMPONENT, AND WIRE HARNESS

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventor: Takaaki ITO, Osaka (JP)

(21) Appl. No.: 18/709,997

(22) PCT Filed: Nov. 17, 2022
(86) PCT No.: PCT/JP2022/042655

§ 371 Date: May 14, 2024

(30) Foreign Application Priority Data
Nov. 18, 2021 (JP) 2021-188048

(51) Int. Cl. B60R 16/02; H01R 4/64

(52) U.S. Cl. CPC B60R 16/0215; H01R 4/64

(57) ABSTRACT

A clamp (31) according to one aspect of the present disclosure includes an electrically conductive protrusion (32) that is to be inserted into a tubular member (21) from outside of the tubular member (21), the tubular member (21) including a tubular exterior cover portion (22) through which at least one electric wire (11) passes and an electrically conductive shield portion (23) that covers an inner peripheral surface of the exterior cover portion (22). Also, the clamp (31) includes a contact portion (33) arranged between an electrically conductive attachment target (100) and the protrusion (32). The contact portion (33) is electrically conductive, comes into contact with the attachment target (100), and electrically connects the protrusion (32) and the attachment target (100) to each other.

### TECHNICAL FIELD

The present disclosure relates to a clamp, an electromagnetic shielding component, and a wire harness.

### BACKGROUND

Conventionally, some wire harnesses used in vehicles such as automobiles have included a shield portion that electromagnetically shields an electric wire. The shield portion is electrically conductive and surrounds the outer periphery of the electric wire. The shield portion exhibits an electromagnetic shielding function by being grounded to the vehicle body, for example. Also, some wire harnesses have included a tubular exterior cover portion, such as a corrugated tube, to protect the electric wire.

An example of a component that can easily ground a component included in a wire harness is a band clamp described in Patent Document 1. This band clamp is made of a highly electrically conductive resin. The band clamp is wrapped around the outer periphery of the electric wire included in the wire harness, so as to be in contact with a component of the wire harness to be grounded. The band clamp is then fixed to the vehicle body while in contact with the vehicle body by being inserted into an attachment hole of the vehicle body panel. When the band clamp is fixed to the vehicle body, the component of the wire harness that is to be grounded is grounded to the vehicle body via the band clamp. That is, the component of the wire harness to be grounded can be grounded to the vehicle body without using a grounding terminal.

### PRIOR ART DOCUMENT

### Patent Document

Patent Document 1: JP 2001-357910 A

### SUMMARY OF THE INVENTION

### Problems to be Solved

It is conceivable to use the band clamp described in Patent Document 1 in order to easily ground the shield portion. When the shield portion is exposed by being arranged outside the exterior cover portion, the band clamp can be easily wrapped around the exterior cover portion so as to be in contact with the shield portion. Thereafter, by inserting the band clamp into the attachment hole of the vehicle body panel, the shield portion can be easily grounded to the vehicle body via the band clamp.

However, when the shield portion is arranged inside the exterior cover portion, even if the band clamp described in Patent Document 1 is wrapped around the outer periphery of the exterior cover portion, the band clamp does not come into contact with the shield portion. That is, the shield portion and the band clamp are not electrically connected to each other. For this reason, it is difficult to easily ground the shield portion using the band clamp. In view of this, it is desirable to easily ground the shield portion also when the shield portion is arranged inside the exterior cover portion.

An object of the present disclosure is to provide a clamp, an electromagnetic shielding component, and a wire harness, according to which a shield portion arranged inside an exterior cover portion can be easily grounded.

### Means to Solve the Problem

A clamp of the present disclosure is a clamp including: an electrically conductive protrusion that is to be inserted into a tubular member from outside of the tubular member, the tubular member including a tubular outer cover portion through which at least one electric wire passes and an electrically conductive shield portion that covers an inner peripheral surface of the exterior cover portion; and a contact portion arranged between an electrically conductive attachment target and the protrusion, in which the contact portion is electrically conductive, comes into contact with the attachment target, and electrically connects the protrusion and the attachment target to each other.

An electromagnetic shielding component according to the present disclosure is an electromagnetic shielding component including: a tubular member including a tubular outer cover portion through which at least one electric wire passes and an electrically conductive shield portion that covers an inner peripheral surface of the exterior cover portion; and the above-described clamp, in which the protrusion is inserted into the tubular member from outside of the tubular member and comes into contact with the shield portion.

A wire harness according to the present disclosure is a wire harness including: the above-described electromagnetic shielding component; and at least one electric wire passing through the tubular member.

### Effect of the Invention

According to the clamp, the electromagnetic shielding component, and the wire harness of the present disclosure, the shield portion arranged inside the exterior cover portion can be easily grounded.

### BRIEF DESCRIPTION OF THE DRAWINGS

FIG. 1 is a cross-sectional view schematically showing a wire harness according to an embodiment.

FIG. 2 is a vertical cross-sectional view schematically showing a wire harness according to an embodiment.

FIG. 3 is a cross-sectional view schematically showing part of a wire harness according to a modified example.

FIG. 4 is a cross-sectional view schematically showing part of a wire harness according to a modified example.

FIG. 5 is a cross-sectional view schematically showing part of a wire harness according to a modified example.

FIG. 6 is a cross-sectional view schematically showing part of a wire harness according to a modified example.

FIG. 7 is a cross-sectional view schematically showing a wire harness according to a modified example.

### DETAILED DESCRIPTION TO EXECUTE THE INVENTION

### [Description of Embodiments of the Present Disclosure]

First, embodiments of the present disclosure will be listed and described.

[1] A clamp according to the present disclosure is a clamp including: an electrically conductive protrusion that is to be inserted into a tubular member from outside of the tubular member, the tubular member including a tubular outer cover portion through which at least one electric wire passes and an electrically conductive shield portion that covers an inner peripheral surface of the exterior cover portion; and a contact portion arranged between an electrically conductive attachment target and the protrusion, in which the contact portion is electrically conductive, comes into contact with the attachment target, and electrically connects the protrusion and the attachment target to each other.

According to this configuration, by inserting the protrusion from the outside of the tubular member toward the inside of the tubular member, it is possible to bring the protrusion into contact with the shield portion located inside the exterior cover portion. When the protrusion comes into contact with the shield portion, the shield portion and the contact portion are electrically connected to each other via the protrusion. Accordingly, the shield portion arranged inside the exterior cover portion and the clamp can easily be electrically connected to each other. That is, even if the portion of the tubular member that is to be electrically connected to the clamp is not exposed, the portion that is to be electrically connected and the clamp can be electrically connected to each other by inserting the protrusion into the tubular member. When the contact portion comes into contact with the attachment target, the shield portion and the attachment target are electrically connected to each other via the protrusion and the contact portion. If the attachment target is a vehicle body, for example, the shield portion can be grounded via the clamp. Accordingly, the shield portion arranged inside the exterior cover portion can be easily grounded.

[2] It is preferable to further include a fixing portion configured to fix the contact portion to the attachment target.

According to this configuration, by fixing the fixing portion to the attachment target, the contact portion can be fixed to the attachment target. Accordingly, the position and orientation of the contact portion relative to the attachment target are stabilized.

[3] It is preferable that the contact portion has a through hole through which a cable tie can be passed.

According to this configuration, the clamp and the tubular member can be easily fixed to each other by surrounding the outer periphery of the tubular member and tightening the tubular member and the contact portion with the cable tie passing through the through hole.

[4] It is preferable that the contact portion has at least one conduction protrusion that bites into the attachment target.

According to this configuration, the electrical connection between the attachment target and the contact portion becomes more stable.

[5] It is preferable to include a plurality of the protrusions.

According to this configuration, the plurality of protrusions can be inserted from the outside of the tubular member toward the inside of the tubular member. For this reason, the plurality of protrusions can come into contact with the shield portion located inside the exterior cover portion. Accordingly, the electrical connection between the shield portion and the clamp is more stable.

[6] It is preferable that the protrusion has any one of a cone shape, a polygonal pyramid shape, and a needle shape.

According to this configuration, it is easy to insert the protrusion into the tubular member. Also, even if the tubular member does not have a slit or a hole, it is possible to insert the protrusion into the tubular member while forming a hole in the tubular member with the protrusion.

[7] It is preferable that the protrusion has a column portion extending from the contact portion and a bent portion extending in a direction perpendicular to the column portion from a distal end of the column portion.

According to this configuration, after the protrusion is inserted into the tubular member, the bent portion can suppress a case in which the protrusion comes out of the tubular member. Also, due to the bent portion being in contact with the shield portion, the contact area between the shield portion and the protrusion can be increased. Accordingly, due to the bent portion being in contact with the shield portion, the electrical connection between the shield portion and the clamp can be made more stable. Also, it is possible to suppress a case in which the distal end of the protrusion, that is, the distal end of the bent portion, comes into contact with the electric wire passing through the tubular member, a tape member wrapped around the outer periphery of the electric wire passing through the tubular member, or the like.

[8] It is preferable to include two of the protrusions, in which each of the two protrusions has a needle shape that protrudes from the contact portion and has an inclination angle with respect to the contact portion that can be changed, and one protrusion and another protrusion of the two protrusions partially overlap with each other in a direction intersecting a direction in which the one protrusion protrudes from the contact portion, and intersect each other in a view from a direction in which the two protrusions overlap with each other.

According to this configuration, due to the two protrusions being inserted into the tubular member, it is possible to suppress relative movement between the clamp and the tubular member in the length direction of the tubular member, as well as relative movement between the clamp and the tubular member in the peripheral direction around the center line of the tubular member.

[9] It is preferable that the protrusion has a rod-shaped shaft portion extending from the contact portion and a head portion that is provided integrally with a distal end of the shaft portion and has a larger outer diameter than the shaft portion, and a distal end surface of the head portion is a convex spherical surface.

According to this configuration, when the protrusion is inserted into the tubular member such that the head portion is arranged inside the tubular member, the head portion can be brought into contact with the inner peripheral surface of the shield portion. When the head portion comes into contact with the shield portion, the shield portion and the contact portion are electrically connected to each other via the protrusion. Also, the distal end surface of the head portion is a convex spherical surface. For this reason, it is suitable regardless of whether the head portion comes into contact with the electric wire passing through the tubular member, a tape member wrapped around the outer periphery of the electric wire passing through the tubular member, or the like.

[10] An electromagnetic shielding component of the present disclosure is an electromagnetic shielding component, including: a tubular member including a tubular outer cover portion through which at least one electric wire passes and an electrically conductive shield portion that covers an inner peripheral surface of the exterior cover portion; and the above-described clamp, in which the protrusion is inserted into the tubular member from outside of the tubular member and comes into contact with the shield portion.

According to this configuration, the same operations and effects as the above-described clamp can be achieved.

[11] It is preferable that the protrusion protrudes from the contact portion, and a protrusion amount of the protrusion from the contact portion is larger than a thickness of the exterior cover portion and smaller than a sum of the thickness of the exterior cover portion and a thickness of the shield portion.

According to this configuration, the distal end of the protrusion is arranged within the range of the thickness of the shield portion. Accordingly, it is easier to bring the protrusion into contact with the shield portion. Furthermore, it is possible to suppress a case in which the protrusion comes into contact with the electric wire passing through the tubular member, a tape member wrapped around the outer periphery of the electric wire passing through the tubular member, or the like.

[12] It is preferable that the tubular member further includes a protective portion that covers an inner peripheral surface of the shield portion inside of the shield portion.

According to this configuration, it is possible to suppress a case in which the electric wire passing through the tubular member comes into direct contact with the shield portion. Accordingly, the shield portion can be suitably protected. Also, if the distal end of the protrusion is arranged outside the inner peripheral surface of the protective portion, it is possible to suppress a case in which the protrusion comes into contact with the electric wire passing through the tubular member, a tape member wrapped around the outer periphery of the electric wire passing through the tubular member, or the like.

[13] It is preferable to further include a tightening member that passes through the contact portion, surrounds an outer periphery of the tubular member, and tightens the tubular member and the contact portion.

According to this configuration, the clamp and the tubular member can be fixed by the tightening member.

[14] A wire harness of the present disclosure is a wire harness including: the above-described electromagnetic shielding component; and at least one electric wire passing through the tubular member.

According to this configuration, the same operations and effects as the above-described clamp and the above-described electromagnetic shielding component can be achieved.

### [Details of Embodiments of the Present Disclosure]

Specific examples of the clamp, the electromagnetic shielding component, and the wire harness according to the present disclosure will be described below with reference to the drawings. In each drawing, parts of the configuration may be exaggerated or simplified for convenience of description. Also, in each drawing, the dimensional proportions of the portions may differ from the actual ones or from those in other drawings. “Vertical” in this specification includes not only strictly vertical, but also approximately vertical within a range in which the operations and effects of this embodiment are exhibited. Also, the term “tubular” used in this specification refers not only to an object in which a peripheral wall is formed continuously around the periphery, but also to an object in which a plurality of parts are combined to form a cylindrical shape, and to an object having a gap in a portion thereof in the peripheral direction, as with a C shape. Also, a “tubular” outer edge shape includes, but is not limited to, a circular shape, an oval shape, and a polygonal shape with sharp or rounded corners. Note that the present invention is not limited to these examples, but is indicated by the scope of the claims, and all changes within the meaning and scope equivalent to the scope of the claims are intended to be encompassed therein.

Hereinafter, one embodiment of a clamp, an electromagnetic shielding component, and a wire harness will be described.

### (Overall Configuration of Wire Harness 10)

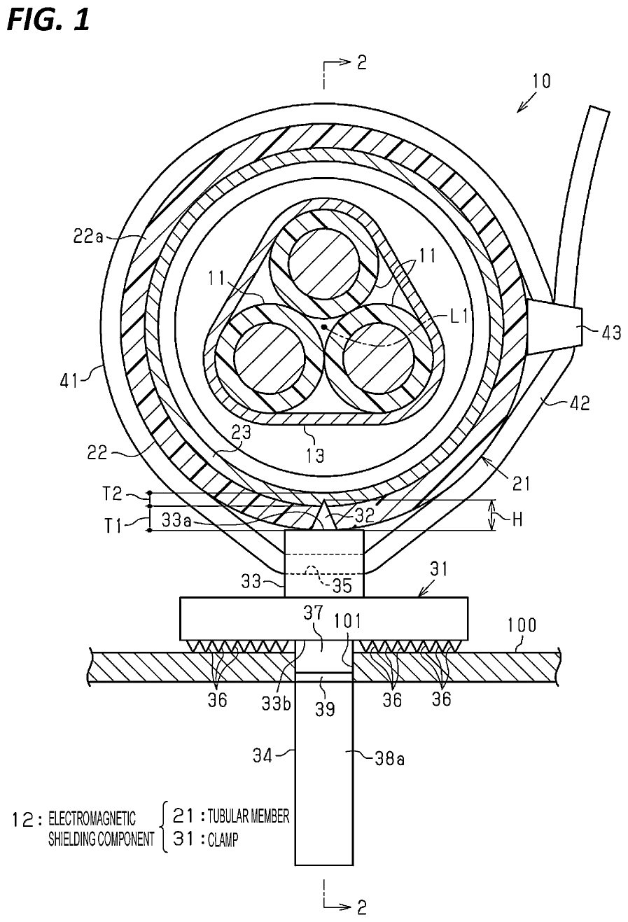

A wire harness 10 shown in FIG. 1 is mounted in a vehicle such as an automobile, for example. The wire harness 10 electrically connects two or three or more electrical devices mounted in a vehicle. The wire harness 10 includes at least one electric wire 11 and an electromagnetic shielding component 12 that electromagnetically shields the electric wire 11. Note that, as an example, FIG. 1 shows a wire harness 10 including three electric wires 11. However, the number of electric wires 11 included in the wire harness 10 is not limited to three, as long as it is one or more. The plurality of electric wires 11 may be bundled with a tape member 13. The tape member 13 is, for example, a PVC (polyvinyl chloride) tape. Note that the tape member 13 may also be an adhesive tape other than a PVC tape.

### (Configuration of Electromagnetic Shielding Component 12)

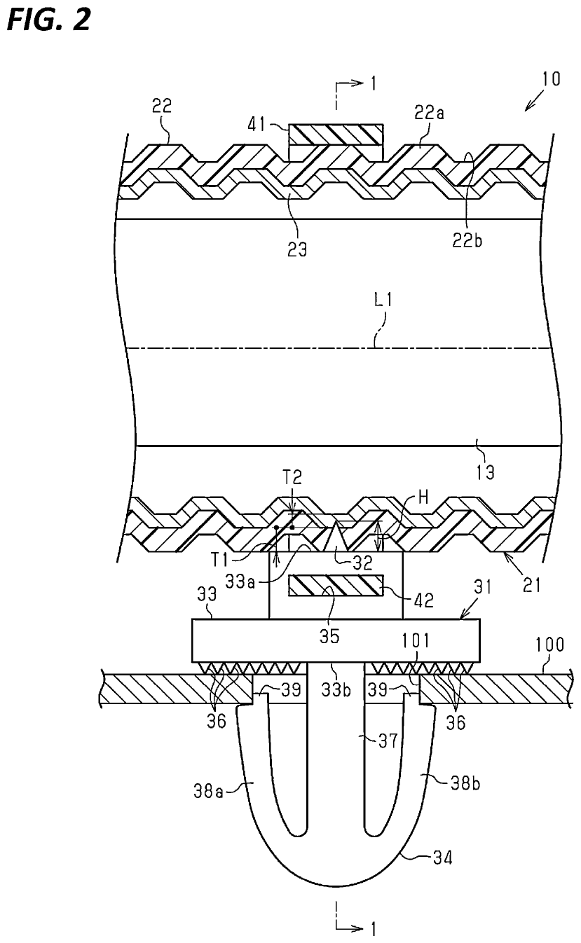

As shown in FIGS. 1 and 2, the electromagnetic shielding component 12 includes a tubular member 21 and a clamp 31. Also, the electromagnetic shielding component 12 may further include a tightening member 41 for fixing the tubular member 21 and the clamp 31. Note that FIG. 1 is a cross-sectional view taken along line 1-1 in FIG. 2. However, in FIG. 1, the clamp 31 and the tightening member 41 are not shown in cross section. Also, FIG. 2 is a cross-sectional view taken along line 2-2 in FIG. 1. However, in FIG. 2, the clamp 31 is not shown in cross section.

### (Configuration of Tubular Member 21)

The tubular member 21 has a tubular exterior cover portion 22 through which at least one electric wire 11 passes, and an electrically conductive shield portion 23 that covers the inner peripheral surface of the exterior cover portion 22.

### (Configuration of Exterior Cover Portion 22)

The exterior cover portion 22 is, for example, a corrugated tube. When the exterior cover portion 22 is a corrugated tube, the exterior cover portion 22 has an accordion shape in which annular protruding portions 22a and annular recessed portions 22b are arranged alternatingly. Each of the annular protruding portions 22a and the annular recessed portions 22b has, for example, an annular shape that goes around a center line L1 of the exterior cover portion 22 in the peripheral direction. Note that the peripheral direction around the center line L1 of the exterior cover portion 22 is hereinafter referred to as the peripheral direction of the exterior cover portion 22. Also, the center line L1 of the exterior cover portion 22 coincides with a center line of the tubular member 21, for example. Accordingly, the peripheral direction of the exterior cover portion 22 coincides with the peripheral direction around the center line of the tubular member 21, for example.

As the material for the exterior cover portion 22, for example, a synthetic resin such as polypropylene can be used. The exterior cover portion 22 is not limited to a corrugated tube made of polypropylene, but may be a tube made of a resin material other than polypropylene, such as nylon, polyolefin, polyamide, polyester, or ABS resin. Also, the exterior cover portion 22 may be a tube having a circular cross section without any unevenness on the surface, or a tube having spiral protruding portions and recessed portions on the surface.

### (Configuration of Shield Portion 23)

It is preferable that the shield portion 23 is arranged so as to be in overall contact with the inner peripheral surface of the exterior cover portion 22. The shield portion 23 is, for example, a metal layer that covers the inner peripheral surface of the exterior cover portion 22. As the material of the shield portion 23, for example, a metal material that is copper-based, aluminum-based, or the like can be used. The shield portion 23 is, for example, provided integrally with the inner peripheral surface of the exterior cover portion 22. The shield portion 23 covers, for example, the inner peripheral surface of the exterior cover portion 22 over the entirety in the peripheral direction of the exterior cover portion 22. Also, the shield portion 23 covers, for example, the inner peripheral surface of the exterior cover portion 22 over the entirety in the length direction of the exterior cover portion 22. Note that the length direction of the exterior cover portion 22 is a direction along the center line L1.

### (Configuration of Clamp 31)

The clamp 31 includes an electrically conductive protrusion 32 and a contact portion 33 arranged between an electrically conductive attachment target 100 and the protrusion 32. Also, the clamp 31 may further include a fixing portion 34 that fixes the contact portion 33 to the attachment target 100.

The attachment target 100 is, for example, an electrically conductive vehicle body panel. The attachment target 100 has an attachment hole 101 for attaching the clamp 31, for example. If the attachment target 100 is a vehicle body panel, the attachment hole 101 passes through the vehicle body panel. Note that the attachment target 100 is not limited to a vehicle body panel, and may be, for example, an electrically conductive bracket fixed to a vehicle body panel.

### (Configuration of Contact Portion 33)

The contact portion 33 is a portion arranged between the protrusion 32 of the clamp 31 and the attachment target 100. The contact portion 33 has, for example, a first surface 33a that opposes the outer peripheral surface of the tubular member 21. Also, the contact portion 33 has, for example, a second surface 33b that opposes the attachment target 100. The second surface 33b is located, for example, at the end surface of the contact portion 33 on the side opposite to the first surface 33a.

The contact portion 33 may also have a through hole 35 through which the tightening member 41 can pass. The contact portion 33 has the through hole 35 in a portion of the contact portion 33 that is between the first surface 33a and the second surface 33b, for example.

Also, the contact portion 33 may include at least one conduction protrusion 36 that bites into the attachment target 100. For example, the contact portion 33 has a plurality of the conduction protrusions 36. The contact portion 33 has, for example, a plurality of the conduction protrusions 36 on the second surface 33b. That is, the plurality of conduction protrusions 36 protrude from the second surface 33b. Each of the conduction protrusions 36 has a sharp distal end so that it can bite into the attachment target 100. For example, each conduction protrusion 36 has one of a conical shape, a polygonal pyramid shape, and a needle shape. Note that the term “needle shape” used in this specification means a rod-like shape with a sharp distal end.

The contact portion 33 is electrically conductive. As the material of the contact portion 33, for example, a metal material can be used. Note that the material of the contact portion 33 is not limited to a metal material, and for example, an electrically conductive resin material can also be used.

### (Configuration of Protrusion 32)

The protrusion 32 protrudes from the contact portion 33. For example, the protrusion 32 protrudes from the first surface 33a. For example, the protrusion 32 has a sharp distal end. For example, the protrusion 32 has a conical shape, a polygonal pyramid shape, or a needle shape.

A protrusion amount H of the protrusion 32 from the contact portion 33 is, for example, larger than a thickness T1 of the exterior cover portion 22 and smaller than the sum of the thickness T1 of the exterior cover portion 22 and a thickness T2 of the shield portion 23. Note that the protrusion amount H of the protrusion 32 need only be larger than at least the thickness T1 of the exterior cover portion 22.

For example, the protrusion 32 is provided in one piece with the contact portion 33. Also, the protrusion 32 is electrically connected to the contact portion 33. Note that the protrusion 32 may also be formed separately from the contact portion 33. In this case, the protrusion 32 is fixed to the contact portion 33 so as to be electrically connected to the contact portion 33.

### (Configuration of Fixing Portion 34)

The fixing portion 34 is provided integrally with the contact portion 33. For example, the fixing portion 34 may be provided in one piece with the contact portion 33. Also, for example, the fixing portion 34 may be provided separately from the contact portion 33 and be fixed to the contact portion 33. As the material of the fixing portion 34, a metal material or a synthetic resin material can be used.

For example, the fixing portion 34 protrudes from the second surface 33b. The fixing portion 34 includes, for example, an attachment support 37 protruding from the second surface 33b, and a pair of engagement claws 38a and 38b extending from the distal end region of the attachment support 37. That is, the fixing portion 34 may have an arrowhead shape having the attachment support 37 and the pair of engagement claws 38a and 38b.

The attachment support 37 is located between the engagement claw 38a and the engagement claw 38b. Each of the engagement claws 38a and 38b extends from the distal end region of the attachment support 37 in a direction approaching the base end of the attachment support 37. Each of the engagement claws 38a and 38b is located father away from the attachment support 37 from its base end toward its distal end. Each of the engagement claws 38a and 38b has elasticity. Each of the engagement claws 38a and 38b can be elastically deformed so that the distal end thereof approaches the attachment support 37.

Each of the engagement claws 38a and 38b may have a positioning protrusion 39 at its distal end. The positioning protrusion 39 protrudes from an end region near the attachment support 37 on the distal end surface of each of the engagement claws 38a and 38b.

### (Configuration of Tightening Member 41)

The tightening member 41 is, for example, a cable tie made of a synthetic resin or metal. The tightening member 41 is, for example, a cable tie made of a synthetic resin. If the tightening member 41 is a cable tie, the tightening member 41 includes a band portion 42 having an elongated flat plate shape and a lock portion 43 provided at one end in the length direction of the band portion 42.

The lock portion 43 has a lock hole (not shown) into which the band portion 42 can be inserted. The other end in the length direction of the band portion 42 is passed through the lock hole. When the other end of the band portion 42 is passed through the lock portion 43, the lock portion 43 allows the band portion 42 to move relative to the lock portion 43 in a direction in which the inner region of the band portion 42 becomes smaller. On the other hand, when the other end of the band portion 42 is passed through the lock portion 43, the lock portion 43 prevents the band portion 42 from moving relative to the lock portion 43 in the direction in which the inner region of the band portion 42 becomes larger. For example, the lock portion 43 has an engagement piece (not shown) that protrudes from the inner peripheral surface of the lock hole into the inside of the lock hole. Also, for example, the band portion 42 has a plurality of engagement grooves (not shown) arranged side by side in the length direction of the band portion 42. Due to the engagement piece being caught in the engagement grooves, movement of the band portion 42 relative to the lock portion 43 in a direction in which the inner region of the band portion 42 becomes larger is prevented.

### (Fixing Clamp 31 to Tubular Member 21)

When the clamp 31 is attached to the tubular member 21, the protrusion 32 is first inserted into the tubular member 21 from the outside of the tubular member 21 toward the inside of the tubular member 21. For example, the protrusion 32 is inserted into the exterior cover portion 22 from the distal end surface of one annular protruding portion 22a. Also, the protrusion 32 is inserted into the tubular member 21 along the radial direction of the exterior cover portion 22. At this time, the protrusion 32 is inserted into the tubular member 21 while the protrusion 32 forms a hole in the exterior cover portion 22. Note that the radial direction of the exterior cover portion 22 is the thickness direction of the exterior cover portion 22, and is a direction perpendicular to the center line L1.

Thereafter, the band portion 42 of the tightening member 41 is passed through the through hole 35. The band portion 42 of the tightening member 41 passes through the contact portion 33 by passing through the through hole 35. Note that the band portion 42 may also be passed through the through hole 35 before the protrusion 32 is inserted into the tubular member 21. The band portion 42 is passed through the lock portion 43 while being wrapped around the outer periphery of the tubular member 21 so as to surround the outer periphery of the tubular member 21. The band portion 42 tightens the tubular member 21 and the contact portion 33 due to the portion of the band portion 42 that has passed through the lock portion 43 being pulled. As a result, the clamp 31 is fixed to the tubular member 21 by the tightening member 41.

When the clamp 31 is fixed to the tubular member 21, the distal end of the protrusion 32 reaches the shield portion 23. For this reason, the protrusion 32 comes into contact with the shield portion 23. Accordingly, the protrusion 32 and the shield portion 23 are electrically connected to each other. That is, the shield portion 23 and the clamp 31 are electrically connected to each other. Also, when the clamp 31 is fixed to the tubular member 21, the first surface 33a may be in contact with the outer peripheral surface of the tubular member 21.

Note that the protrusion 32 may reach the shield portion 23 before the tightening member 41 tightens the tubular member 21 and the contact portion 33. Also, when the tightening member 41 tightens the tubular member 21 and the contact portion 33, the protrusion 32 may reach the shield portion 23 due to being pushed toward the inside of the tubular member 21 by the force of the tightening member 41 tightening the tubular member 21 and the contact portion 33.

### (Fixing Clamp 31 to Attachment Target 100)

The clamp 31 attached to the tubular member 21 is fixed to the attachment target 100 by the fixing portion 34. When the clamp 31 is attached to the attachment target 100, the fixing portion 34 is inserted into the attachment hole 101. At this time, each of the engagement claws 38a and 38b is pushed by the inner peripheral surface of the attachment hole 101, and thereby elastically deforms such that the distal end approaches the attachment support 37. Each of the engagement claws 38a and 38b returns to its original shape upon passing through the attachment hole 101. The distal end surfaces of each of the engagement claws 38a and 38b that have returned to their original shapes oppose the outer periphery of the attachment hole 101 in the attachment target 100. Also, a portion of the outer periphery of the attachment hole 101 in the attachment target 100 is sandwiched between the distal end surface of each of the engagement claws 38a and 38b and the contact portion 33. As a result, the fixing portion 34 enters a state in which the clamp 31 is fixed to the attachment target 100. Note that each positioning protrusion 39 comes into contact with the inner peripheral surface of the attachment hole 101, thereby suppressing relative movement between the fixing portion 34 and the attachment target 100 in a direction perpendicularly intersecting the penetration direction of the attachment hole 101.

When the clamp 31 is attached to the attachment target 100, the contact portion 33 comes into contact with the attachment target 100 and electrically connects the protrusion 32 and the attachment target 100 to each other. Specifically, for example, the contact portion 33 is arranged with the second surface 33b opposing the attachment target 100. Furthermore, each of the plurality of conduction protrusions 36 is pressed against the attachment target 100 by the force with which the fixing portion 34 fixes the clamp 31 to the attachment target 100, for example. Note that the contact portion 33 may also be pressed against the attachment target 100 by a worker when attaching the fixing portion 34 to the attachment target 100. Each of the plurality of conduction protrusions 36 bites into the attachment target 100 by being pressed against the attachment target 100. For example, if the surface of the vehicle body panel that is the attachment target 100 is coated for rust prevention, each of the plurality of conduction protrusions 36 penetrates through the coating and bites into the metal portion of the vehicle body panel. For this reason, each of the plurality of conduction protrusions 36 is electrically connected to the attachment target 100. That is, the contact portion 33 is electrically connected to the attachment target 100. When the contact portion 33 is electrically connected to the attachment target 100, the shield portion 23 is electrically connected to the attachment target 100 via the protrusion 32 and the contact portion 33. That is, the shield portion 23 is grounded to the vehicle body via the protrusion 32 and the contact portion 33. The shield portion 23 exhibits an electromagnetic shielding function by being grounded to the vehicle body.

### (Operations and Effects of Embodiment)

The operations and effects of this embodiment will be described.

(1) The clamp 31 includes an electrically conductive protrusion 32 that is inserted into the tubular member 21 from outside the tubular member 21, the tubular member 21 having a tubular exterior cover portion 22 through which at least one electric wire 11 passes and an electrically conductive shield portion 23 that covers the inner peripheral surface of the exterior cover portion 22. Also, the clamp 31 includes a contact portion 33 arranged between the electrically conductive attachment target 100 and the protrusion 32. The contact portion 33 is electrically conductive, comes into contact with the attachment target 100, and electrically connects the protrusion 32 and the attachment target 100 to each other.

According to this configuration, by inserting the protrusion 32 from the outside of the tubular member 21 toward the inside of the tubular member 21, it is possible to bring the protrusion 32 into contact with the shield portion 23 located inside the exterior cover portion 22. When the protrusion 32 comes into contact with the shield portion 23, the shield portion 23 and the contact portion 33 are electrically connected to each other via the protrusion 32. Accordingly, the shield portion 23 arranged inside the exterior cover portion 22 and the clamp 31 can be easily electrically connected to each other. That is, even if the portion of the tubular member 21 that is to be electrically connected to the clamp 31 is not exposed, the portion that is to be electrically connected and the clamp 31 can be electrically connected to each other by inserting the protrusion 32 into the tubular member 21. Then, when the contact portion 33 comes into contact with the attachment target 100, the shield portion 23 and the attachment target 100 are electrically connected to each other via the protrusion 32 and the contact portion 33. If the attachment target 100 is, for example, a vehicle body, the shield portion 23 can be grounded via the clamp 31. Accordingly, the shield portion 23 arranged inside the exterior cover portion 22 can be easily grounded.

Also, the protrusion 32 is electrically connected to the shield portion 23 by being inserted into the tubular member 21. For this reason, the protrusion 32 and the shield portion 23 can be easily electrically connected to each other at any position of the tubular member 21 in the length direction of the tubular member 21.

(2) The clamp 31 further includes a fixing portion 34 that fixes the contact portion 33 to the attachment target 100. According to this configuration, by fixing the fixing portion 34 to the attachment target 100, the contact portion 33 can be fixed to the attachment target 100. Accordingly, the position and orientation of the contact portion 33 relative to the attachment target 100 are stabilized.

(3) The contact portion 33 has a through hole 35 through which a cable tie can pass. According to this configuration, the clamp 31 and the tubular member 21 can be easily fixed to each other by surrounding the outer periphery of the tubular member 21 and tightening the tubular member 21 and the contact portion 33 with the cable tie passing through the through hole 35.

(4) The contact portion 33 has at least one conduction protrusion 36 that bites into the attachment target 100. According to this configuration, the electrical connection between the attachment target 100 and the contact portion 33 is easily stabilized.

(5) The protrusion 32 has one of a conical shape, a polygonal pyramid shape, or a needle shape. According to this configuration, it is easy to insert the protrusion 32 into the tubular member 21. Also, even if the tubular member 21 does not have a slit or a hole, it is possible to insert the protrusion 32 into the tubular member 21 while forming a hole in the tubular member 21 with the protrusion 32.

(6) The electromagnetic shielding component 12 includes a tubular member 21 having a tubular exterior cover portion 22 through which at least one electric wire 11 passes and an electrically conductive shield portion 23 that covers the inner peripheral surface of the exterior cover portion 22, and a clamp 31. The protrusion 32 is inserted into the tubular member 21 from the outside of the tubular member 21 and comes into contact with the shield portion 23. According to this configuration, it is possible to obtain the electromagnetic shielding component 12 including the clamp 31 that exhibits the above-mentioned operations and effects.

(7) The protrusion 32 protrudes from the contact portion 33. The protrusion amount H of the protrusion 32 from the contact portion 33 is greater than the thickness T1 of the exterior cover portion 22 and smaller than the sum of the thickness T1 of the exterior cover portion 22 and the thickness T2 of the shield portion 23. According to this configuration, the distal end of the protrusion 32 is arranged within the range of the thickness T2 of the shield portion 23. Accordingly, it is easier to bring the protrusion 32 into contact with the shield portion 23. Furthermore, it is possible to suppress a case in which the protrusion 32 comes into contact with the electric wire 11 passing through the tubular member 21, the tape member 13 wrapped around the outer periphery of the electric wire 11 passing through the tubular member 21, or the like.

(8) The electromagnetic shielding component 12 further includes a tightening member 41 that passes through the contact portion 33, surrounds the outer periphery of the tubular member 21, and tightens the tubular member 21 and the contact portion 33. According to this configuration, the clamp 31 and the tubular member 21 can be fixed to each other by the tightening member 41.

(9) The wire harness 10 includes an electromagnetic shielding component 12 and at least one electric wire 11 passing through the tubular member 21. According to this configuration, it is possible to obtain the wire harness 10 including the clamp 31 and the electromagnetic shielding component 12 that exhibits the above-mentioned operations and effects.

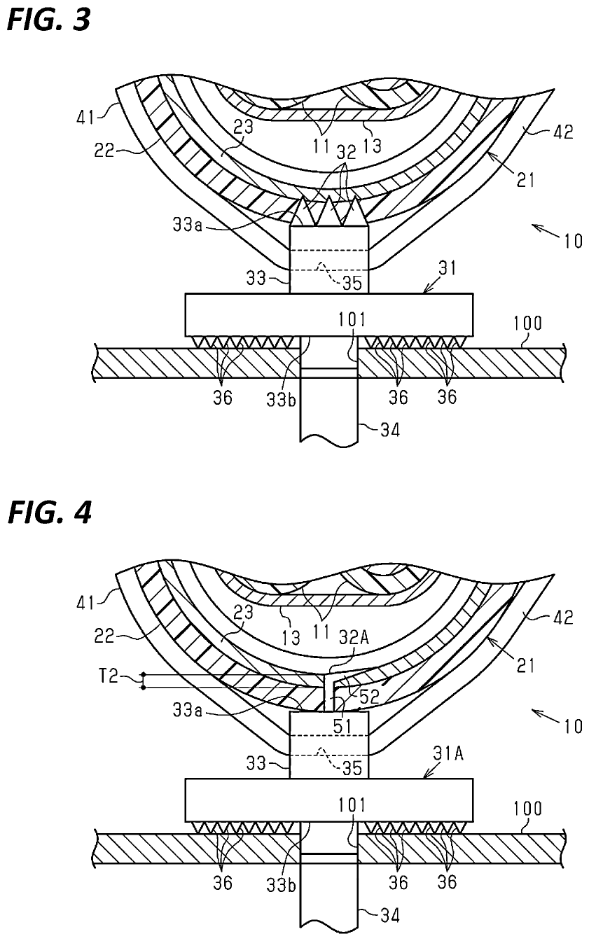

This embodiment can be implemented with the following modifications. This embodiment and the following modified examples can be implemented in combination with each other as long as no technical contradiction occurs.
The protrusion amount H of the protrusion 32 from the contact portion 33 may also be larger than the sum of the thickness T1 of the exterior cover portion 22 and the thickness T2 of the shield portion 23. However, the protrusion amount H of the protrusion 32 is preferably a value according to which the protrusion 32 does not come into contact with the electric wire 11 passing through the tubular member 21, the tape member 13 wrapped around the outer periphery of the electric wire 11 passing through the tubular member 21, or the like.
As shown in FIG. 3, the clamp 31 may also include a plurality of protrusions 32. FIG. 3 shows the clamp 31 having three protrusions 32 as an example. When the clamp 31 includes a plurality of protrusions 32, the number of protrusions 32 is not limited to three, and may be two or four or more. The plurality of protrusions 32 may be arranged side by side in the longitudinal direction of the exterior cover portion 22, or may be arranged side by side in the peripheral direction of the exterior cover portion 22.

In this way, the plurality of protrusions 32 can be inserted from the outside of the tubular member 21 toward the inside of the tubular member 21. For this reason, the plurality of protrusions 32 can come into contact with the shield portion 23 located inside of the exterior cover portion 22. Accordingly, the electrical connection between the shield portion 23 and the clamp 31 is more stable.
The shape of the protrusion 32 is not limited to the shape of the above-described embodiment. The protrusion 32 may have any shape as long as it can be inserted into the tubular member 21 from the outside of the tubular member 21.

For example, a clamp 31A shown in FIG. 4 is provided in the wire harness 10 of the above-described embodiment instead of the clamp 31. The clamp 31A has a protrusion 32A instead of the protrusion 32 of the above-described embodiment. The protrusion 32A has a column portion 51 extending from the contact portion 33, and a bent portion 52 extending from the distal end of the column portion 51 in a direction intersecting the column portion 51. The column portion 51 has, for example, a rod shape extending from the first surface 33a. The distal end of the bent portion 52 has a sharp shape so that it can be inserted into the tubular member 21. The column portion 51 and the bent portion 52 may be configured to form any angle, and for example, form an angle of about 90°.

When the protrusion 32A is inserted into the tubular member 21, the bent portion 52 is first inserted into the tubular member 21 from the outside of the tubular member 21 along the radial direction of the exterior cover portion 22. Thereafter, the contact portion 33 is rotated such that the distal end of the column portion 51 is moved toward the inside of the tubular member 21. Then, the column portion 51 is arranged along the radial direction of the exterior cover portion 22 and the bent portion 52 is arranged along the peripheral direction of the exterior cover portion 22. In this state, insertion of the protrusion 32A into the tubular member 21 is completed.

When the protrusion 32A is inserted into the tubular member 21, the distal end region of the column portion 51 comes into contact with the shield portion 23. Also, since the bent portion 52 is arranged along the peripheral direction of the exterior cover portion 22, the bent portion 52 is in contact with the shield portion 23 over the entire area between the base end and the distal end of the bent portion 52 or over a partial region between the base end and the distal end of the bent portion 52. Note that the bent portion 52 may also be arranged within the range of the thickness T2 of the shield portion 23, or may be arranged adjacent to the inner peripheral surface of the shield portion 23.

In this way, after the protrusion 32A is inserted into the tubular member 21, the bent portion 52 can suppress a case in which the protrusion 32A comes out of the tubular member 21. Also, due to the bent portion 52 coming into contact with the shield portion 23, the contact area between the shield portion 23 and the protrusion 32A can be increased. Accordingly, due to the bent portion 52 coming into contact with the shield portion 23, the electrical connection between the shield portion 23 and the clamp 31 can be made more stable. Also, it is possible to prevent a case in which the distal end of the protrusion 32A, that is, the distal end of the bent portion 52, comes into contact with the electric wire 11 passing through the tubular member 21, the tape member 13 wrapped around the outer periphery of the electric wire 11 passing through the tubular member 21, or the like.

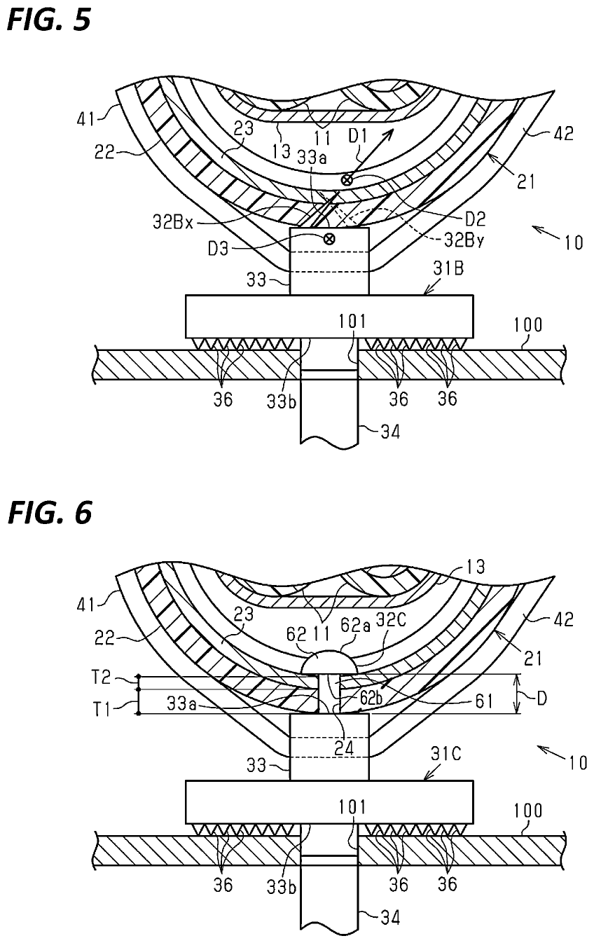

Also, for example, a clamp 31B shown in FIG. 5 is provided in the wire harness 10 of the above-described embodiment instead of the clamp 31. The clamp 31B has two protrusions 32Bx and 32By instead of the protrusion 32 of the above-described embodiment. Each of the two protrusions 32Bx and 32By has a needle shape that protrudes from the contact portion 33. Also, each of the two protrusions 32Bx and 32By has an inclination angle with respect to the contact portion 33 that can be changed. For example, each of the two protrusions 32Bx and 32By protrudes from the first surface 33a. Also, the inclination angle with respect to the first surface 33a of each of the two protrusions 32Bx and 32By can be changed by, for example, being rotated using the base end as a rotation center.

One protrusion 32Bx and the other protrusion 32By of the two protrusions 32Bx and 32By partially overlap with each other in a direction D2 intersecting a direction D1 in which the one protrusion 32Bx protrudes from the contact portion 33, and intersect each other in a view from a direction D3 in which the protrusions 32Bx and 32By overlap with each other. The direction D2 is, for example, a direction perpendicularly intersecting the direction D1. Also, the direction D3 is, for example, the same direction as the direction D2. The one protrusion 32Bx and the other protrusion 32By intersect, for example, in an X shape in a view from the direction D3.

In this way, by inserting the two protrusions 32Bx and 32By into the tubular member 21, relative movement between the clamp 31B and the tubular member 21 in the length direction of the tubular member 21 can be suppressed. Also, by inserting the two protrusions 32Bx and 32By into the tubular member 21, relative movement between the clamp 31B and the tubular member 21 in the peripheral direction around the center line of the tubular member 21, that is, in the peripheral direction of the exterior cover portion 22, can be suppressed.

Also, for example, a clamp 31C shown in FIG. 6 is provided in the wire harness 10 of the above-described embodiment instead of the clamp 31. The clamp 31C has a protrusion 32C instead of the protrusion 32 of the above-described embodiment. The protrusion 32C has a rod-shaped shaft portion 61 extending from the contact portion 33, and a head portion 62 that is integrally provided at the distal end of the shaft portion 61 and has a larger outer diameter than the shaft portion 61. The distal end surface 62a of the head portion 62 is a convex spherical surface. The base end surface 62b of the head portion 62 can be a surface of any shape, but is, for example, a plane perpendicular to the direction in which the shaft portion 61 extends. That is, the head portion 62 may have a shape obtained by cutting out part of a sphere, for example.

The tubular member 21 may have a slit 24 extending along the center line L1 of the exterior cover portion 22. Note that although the center line L1 is not shown in FIG. 6, it is the same as the center line L1 shown in FIG. 1. The slit 24 extends from one end of the tubular member 21 to the other end in the length direction of the tubular member 21. The protrusion 32C is inserted into the tubular member 21 from the slit 24. The head portion 62 is arranged inside the tubular member 21, while the shaft portion 61 is arranged in a state of passing through the slit 24. The protrusion 32C is electrically connected to the shield portion 23 due to the head portion 62 coming into contact with the shield portion 23. For example, the protrusion 32C is electrically connected to the shield portion 23 by the base end surface 62b of the head portion 62 coming into contact with the inner peripheral surface of the shield portion 23. Note that the distance D between the base end surface 62b and the first surface 33a of the head portion 62 is preferably a value equal or equivalent to the sum of the thickness T1 of the exterior cover portion 22 and the thickness T2 of the shield portion 23.

According to this configuration, when the protrusion 32C is inserted into the tubular member 21 such that the head portion 62 is arranged inside the tubular member 21, the head portion 62 can be brought into contact with the inner peripheral surface of the shield portion 23. When the head portion 62 comes into contact with the shield portion 23, the shield portion 23 and the contact portion 33 are electrically connected to each other via the protrusion 32C. Also, the distal end surface 62a of the head portion 62 is a convex spherical surface. For this reason, it is suitable even if the head portion 62 comes into contact with the electric wire 11 passing through the tubular member 21, the tape member 13 wrapped around the outer periphery of the electric wire 11 passing through the tubular member 21, or the like.

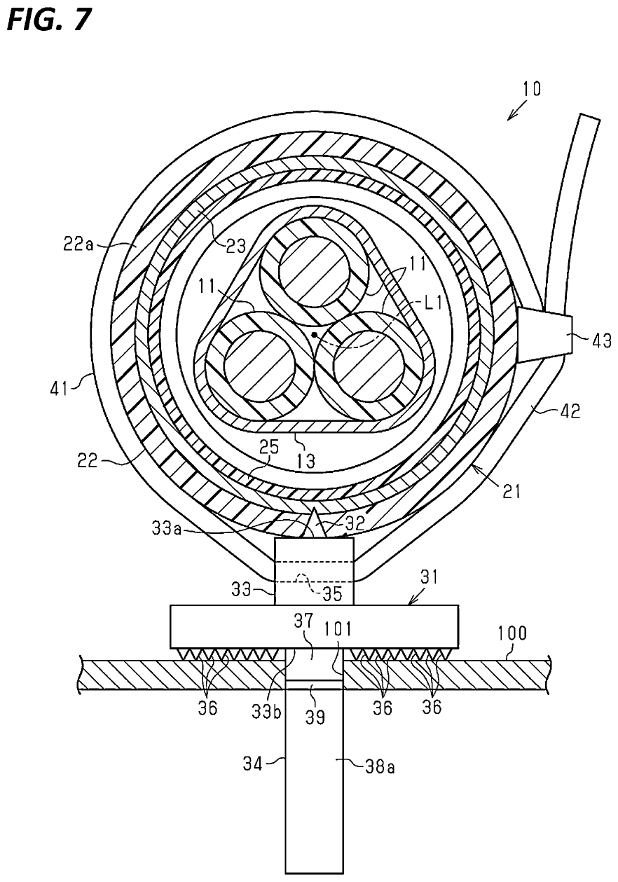

Note that the tubular member 21 may also have an insertion hole for inserting the protrusion 32C instead of the slit 24. The insertion hole passes through the tubular member 21 so as to bring the inside and outside of the tubular member 21 into communication with each other. The inner diameter of the insertion hole is smaller than the outer diameter of the head portion 62 and the same as or larger than the outer diameter of the shaft portion 61. In this case, the protrusion 32C is pushed into the insertion hole toward the inside of the tubular member 21 until the head portion 62 passes through the insertion hole. Even in this case, the same operations and effects as described above can be achieved.
As shown in FIG. 7, the tubular member 21 may further include a protective portion 25 that covers the inner peripheral surface of the shield portion 23 inside the shield portion 23. The protective portion 25 is made of, for example, a synthetic resin material. The protective portion 25 may be made of the same type of synthetic resin material as the exterior cover portion 22, or may be made of a different synthetic resin material from the exterior cover portion 22. As the material of the protective portion 25, for example, a synthetic resin such as polypropylene can be used. The protective portion 25 is not limited to polypropylene, and may be made of a resin material other than polypropylene, such as nylon, polyolefin, polyamide, polyester, or ABS resin.

The protective portion 25 has a film shape that is provided integrally with the exterior cover portion 22, for example. The protective portion 25 covers, for example, the inner peripheral surface of the shield portion 23 over the entire periphery of the exterior cover portion 22 in the peripheral direction. Also, the shield portion 23 covers, for example, the inner peripheral surface of the shield portion 23 over the entirety in the length direction of the exterior cover portion 22. Note that the protective portion 25 may also cover part of the inner peripheral surface of the shield portion 23.

Also, the protective portion 25 does not need to be provided integrally with the exterior cover portion 22. For example, the protective portion 25 may also be a sheet-like or cylindrical member that is interposed between the inner peripheral surface of the shield portion 23 and the electric wire 11 and covers the inner peripheral surface of the shield portion 23. In this case, the sheet-like protective portion 25 is arranged inside the tubular member 21 in a rolled-up state.

This makes it possible to suppress a case in which the electric wire 11 passing through the tubular member 21 comes into direct contact with the shield portion 23. Accordingly, the shield portion 23 can be suitably protected. Also, when the distal end of the protrusion 32 is arranged outside relative to the inner peripheral surface of the protective portion 25, it is possible to suppress a case in which the protrusion 32 comes into contact with the electric wire 11 passing through the tubular member 21, the tape member 13 wrapped around the outer periphery of the electric wire 11 passing through the tubular member 21, or the like.
The contact portion 33 does not need to include the conduction protrusion 36. In this case, for example, the second surface 33b of the contact portion 33 is electrically connected to the attachment target 100 by coming into direct contact with the attachment target 100. Also, for example, instead of the conduction protrusion 36, the contact portion 33 may have an areal contact portion made of an electrically conductive elastomer on the second surface 33b. In this case, the contact portion 33 is electrically connected to the attachment target 100 via the areal contact portion that is in areal contact with the attachment target 100.
The tightening member 41 is not limited to a cable tie. The tightening member 41 may be, for example, an adhesive tape having a base material and an adhesive layer laminated on at least a portion of one side of the base material. Also, the electromagnetic shielding component 12 does not necessarily need to include the tightening member 41. In this case, the contact portion 33 does not need to include the through hole 35. Also, in this case, for example, the contact portion 33 may be fixed to the outer peripheral surface of the tubular member 21 with an adhesive.
The clamp 31 does not need to include the fixing portion 34. In this case, for example, the attachment target 100 may have locking pieces that sandwich the contact portion 33. Also, for example, the contact portion 33 may have an adhesive layer made of an electrically conductive adhesive. In this case, the contact portion 33 is fixed to the attachment target 100 by the adhesive layer. The contact portion 33 is then electrically connected to the attachment target 100 via the adhesive layer.
The tape member 13 may also be an adhesive tape having a softer base material than the PVC tape base material. This is preferable even if the tape member 13 comes into direct contact with the shield portion 23. Also, the wire harness 10 does not need to include the tape member 13.
In the above-described embodiment, the shield portion 23 is a metal layer that covers the inner peripheral surface of the exterior cover portion 22. However, the shield portion 23 may also be a braided wire formed by braiding a plurality of metal wires. In this case, the shield portion 23 is interposed between the inner peripheral surface of the exterior cover portion 22 and the electric wire 11 and covers the inner peripheral surface of the exterior cover portion 22.
In the above-described embodiment, the exterior cover portion 22 is a corrugated tube. However, the exterior cover portion 22 may also be a sheath included in a shielded wire.
The exterior cover portion 22 in the illustrated example may be electrically insulating. The shield portion 23 in the illustrated example may be overlaid on or in areal contact with the inner peripheral surface of the exterior cover portion 22 over the entire length of the exterior cover portion 22 with no gap therebetween.
In the examples shown in FIGS. 1 to 5 and 7, holes and slits for inserting the protrusions 32, 32A, 32Bx, and 32By of the clamps do not need to be formed in the exterior cover portion 22 before the clamps 31, 31A, and 31B are attached.
The clamps 31, 31A, 31B, and 31C in the illustrated example may be for fixing the wire harness 10 to the attachment target 100.
The illustrated clamps 31, 31A, 31B, and 31C may be single components in which the protrusions 32, 32A, 32Bx, 32By, and 32C, the contact portion 33, and the fixing portion 34 are continuously and integrally formed.
The protrusions 32, 32A, 32Bx, 32By, and 32C in the illustrated example may be made of the same material as the contact portion 33.
When the protrusions 32, 32Bx, and 32By shown in the examples shown in FIGS. 1 to 3, 5, and 7 are inserted into the tubular member 21 from the outside in the radial direction, only the distal ends in the insertion direction may be embedded in the shield portion 23, and other parts may be embedded in the exterior cover portion 22.
When the protrusion 32A in the example shown in FIG. 4 is inserted into the tubular member 21 from the outside in the radial direction, the entire bent portion 52 may be embedded in the shield portion 23, or the side surface of the bent portion 52 may be exposed so as to be flush with the inner peripheral surface of the shield portion 23 and the other portion of the bent portion 52 may be embedded in the shield portion 23.
When the protrusion 32C in the example shown in FIG. 6 is inserted into the tubular member 21 from the outside in the radial direction, the shaft portion 61 may pass through the exterior cover portion 22 and the shield portion 23 in the thickness directions thereof, and the head portion 62 may be caught and locked on the inner peripheral surface of the shield portion 23.
The contact portion 33 in the illustrated example may be configured such that when the protrusions 32, 32A, 32Bx, 32By, and 32C are inserted into the tubular member 21 from the outside thereof, the first surface 33a comes into contact with the outer peripheral surface of the tubular member 21, and thus the protrusions 32, 32A, 32Bx, 32By, and 32C are restricted from advancing further in the penetration direction.
The tubular member 21 of the illustrated embodiment is an example of a multilayer composite tube having a length. The tubular exterior cover portion 22 of the illustrated embodiment, or the annular protruding portion 22a and the annular recessed portion 22b of the exterior cover portion 22, is an example of an electrically insulating, cylindrical, radially-outermost layer included in the multilayer composite tube. The electrically conductive shield portion 23 of the illustrated embodiment is an example of an electrically conductive, cylindrical, radially inner layer that is included in the multilayer composite tube and is overlaid on the radially outermost layer in the radial direction. The attachment target 100 of the illustrated embodiment is an example of a ground potential panel including a mount surface that faces the multilayer composite pipe in a non-contact manner, a non-mount surface on a side opposite to the mount surface, an attachment hole 101 that is open on the mount surface and the non-mount surface, and a ground potential. The clamp of the illustrated embodiment is an example of a grounding clamp configured to retrofit the multilayer composite pipe to the mounting surface of the ground potential panel and to ground the multilayer composite pipe to the ground potential panel. As in the illustrated embodiment, the contact portion 33 of the clamp may include an electrically conductive flat base configured to come into direct contact with the mount surface of the ground potential panel, and an electrically conductive pillar that protrudes from the flat base in a first protrusion direction, the electrically conductive pillar having a support surface that comes into direct contact with the radially outermost surface of the multilayer composite tube and supports the radially outermost surface. The protrusion 32 of the illustrated embodiment is an example of an electrically conductive anchor protrusion that protrudes from the support surface of the electrically conductive pillar, for example, in the first protrusion direction, with a protrusion amount. The fixing portion 34 of the clamp in the illustrated embodiment is an example of a clip that protrudes from the flat base in the second protrusion direction. The clip may be elastically deformable in both directions between a reduced diameter state in which the clip can pass through the attachment hole 101 of the ground potential panel and an enlarged diameter state in which the clip cannot pass through the attachment hole 101 in the ground potential panel. As shown in FIG. 2, the fixing portions 34 (e.g., engagement claws 38a, 38b) may be configured to engage with both the non-mount surface of the ground potential panel and the inner surface of the attachment hole 101, and thereby the clamp does not come off of the ground potential panel.
Accordingly, some embodiments of the present disclosure are directed to a grounding clamp configured to retrofit a multilayer composite pipe to a ground potential panel and to ground the multilayer composite pipe to the ground potential panel, the grounding clamp being able to include:
an electrically conductive flat base configured to come into direct contact with a mount surface of the ground potential panel:
an electrically conductive pillar protruding from the flat base in a first protrusion direction; and
a clip protruding from the flat base in a second protrusion direction different from the first protrusion direction,
in which the clip may be elastically deformable in both directions between a reduced diameter state in which the clip can pass through the attachment hole of the ground potential panel and an enlarged diameter state in which the clip cannot pass through the attachment hole in the ground potential panel,
the electrically conductive pillar may include a support surface that comes into direct contact with a radially outermost surface of the multilayer composite tube and supports the radially outermost surface, and an electrically conductive anchor protrusion that protrudes from the support surface with a protrusion amount, and
the electrically conductive anchor protrusion may pass through a cylindrical radially outermost layer of the multilayer composite tube, and the electrically conductive anchor protrusion, for example, a distal end of the electrically conductive anchor protrusion, may come into direct contact with a cylindrical radially inner layer of the multilayer composite tube.
In some embodiments of the present disclosure, the clip may pass through the ground potential panel and engage with the non-mount surface of the ground potential panel, and may be configured to cooperate with the flat base to sandwich the ground potential panel in the thickness direction.
The embodiments disclosed herein are be considered illustrative in all respects and not restrictive. The scope of the present invention is indicated not by the above-mentioned meaning but by the scope of the claims, and meanings equivalent to the scope of the claims and all changes within the scope are intended to be encompassed therein.

### LIST OF REFERENCE NUMERALS

10 Wire harness
11 Electric wire
12 Electromagnetic shielding component
13 Tape member
21 Tubular member
22 Exterior cover portion
22a Annular protruding portion
22b Annular recessed portion
23 Shield portion
24 Slit
25 Protective portion
31, 31A, 31B, 31C Clamp
32, 32A, 32Bx, 32By, 32C Protrusion
33 Contact portion
33a First surface
33b Second surface
34 Fixing portion
35 Through hole
36 Conduction protrusion
37 Attachment support
38a, 38b Engagement claw
39 Positioning protrusion
41 Tightening member (cable tie)
42 Band portion
43 Lock portion
51 Column portion
52 Bent portion
61 Shaft portion
62 Head portion
62a Distal end surface
62b Base end surface
100 Attachment target
101 Attachment hole
D Distance
D1 Direction
D2 Direction
D3 Direction
H Protrusion amount
L1 Center line
T1 Thickness
T2 Thickness

1. A clamp, comprising:
an electrically conductive protrusion that is to be inserted into a tubular member from outside of the tubular member, the tubular member including a tubular outer cover portion through which at least one electric wire passes and an electrically conductive shield portion that covers an inner peripheral surface of the exterior cover portion; and
a contact portion arranged between an electrically conductive attachment target and the protrusion,
wherein the contact portion is electrically conductive, comes into contact with the attachment target, and electrically connects the protrusion and the attachment target to each other.

2. The clamp according to claim 1, further comprising
a fixing portion configured to fix the contact portion to the attachment target.

3. The clamp according to claim 1,
wherein the contact portion has a through hole through which a cable tie can be passed.

4. The clamp according to claim 1,
wherein the contact portion has at least one conduction protrusion that bites into the attachment target.

5. The clamp according to claim 1, comprising
a plurality of the protrusions.

6. The clamp according to claim 1,
wherein the protrusion has any one of a cone shape, a polygonal pyramid shape, and a needle shape.

7. The clamp according to claim 1,
wherein the protrusion has a column portion extending from the contact portion and a bent portion extending in a direction perpendicular to the column portion from a distal end of the column portion.

8. The clamp according to claim 5, comprising
two of the protrusions,
wherein each of the two protrusions has a needle shape that protrudes from the contact portion and has an inclination angle with respect to the contact portion that can be changed, and
one protrusion and another protrusion of the two protrusions partially overlap with each other in a direction intersecting a direction in which the one protrusion protrudes from the contact portion, and intersect each other in a view from a direction in which the two protrusions overlap with each other.

9. The clamp according to claim 1,
wherein the protrusion has a rod-shaped shaft portion extending from the contact portion and a head portion that is provided integrally with a distal end of the shaft portion and has a larger outer diameter than the shaft portion, and
a distal end surface of the head portion is a convex spherical surface.

10. An electromagnetic shielding component, comprising:
a tubular member including a tubular outer cover portion through which at least one electric wire passes and an electrically conductive shield portion that covers an inner peripheral surface of the exterior cover portion; and
the clamp according to claim 1,
wherein the protrusion is inserted into the tubular member from outside of the tubular member and comes into contact with the shield portion.

11. The electromagnetic shielding component according to claim 10,
wherein the protrusion protrudes from the contact portion, and
a protrusion amount of the protrusion from the contact portion is larger than a thickness of the exterior cover portion and smaller than a sum of the thickness of the exterior cover portion and a thickness of the shield portion.

12. The electromagnetic shielding component according to claim 10,
wherein the tubular member further includes a protective portion that covers an inner peripheral surface of the shield portion inside of the shield portion.

13. The electromagnetic shielding component according to claim 10, further comprising
a tightening member that passes through the contact portion, surrounds an outer periphery of the tubular member, and tightens the tubular member and the contact portion.

14. A wire harness, comprising:
the electromagnetic shielding component according to claim 10; and
at least one electric wire passing through the tubular member.
